(19) United States
(12) Patent Application Publication
(10) Pub. No.: US 2008/0308896 A1
(43) Pub. Date: Dec. 18, 2008

(54) Integrated circuit device comprising a gate electrode structure and corresponding method of fabrication

(76) Inventor: Tim Boescke, Dresden (DE)

Correspondence Address: JENKINS, WILSON, TAYLOR & HUNT, P. A., Suite 1200 UNIVERSITY TOWER, 3100 TOWER BLVD.,, DURHAM, NC, 27707, US

(21) Appl. No.: 11/818,108

(22) Filed: Jun. 14, 2007

(51) Int. Cl. H01L 21/4763; H01L 29/00

(52) U.S. Cl. 257/506; 438/591; 257/E21.495; 257/E29.001

(57) ABSTRACT

The present invention provides an integrated circuit device comprising a semiconductor substrate and a gate electrode structure on the semiconductor substrate having at least one insulating layer of dielectric material on said semiconductor substrate and a metal layer on said at least one insulating layer, said metal layer containing niobium (Nb), vanadium (V), chromium (Cr), tungsten (W) and/or molybdenum (Mo).

### BACKGROUND OF THE INVENTION

The present invention relates to an integrated circuit device comprising a semiconductor substrate and at least one gate electrode structure on said semiconductor substrate and to a corresponding method of fabrication.

It is possible to decrease the size of a Metal-Oxide-Semiconductor Field-Effect Transistor (MOSFET) by introducing a metal electrode into the gate electrode of a MOSFET. One example for such a gate electrode is a Metal Inserted Poly Stack (MIPS). A MIPS comprises a gate dielectric base formed on a semiconductor substrate and a thin metal layer formed on the gate dielectric base. Typically, tantalum carbo oxynitride (Ta(CO)N) is utilized as material for said metal layer. The Ta(CO)N layer can be deposited on the gate electrode base by a Chemical Vapor Deposition (CVD) with a layer thickness of about 10 nm or less.

A p-type MIPS with a metal electrode of Ta(CO)N can achieve a work function about 4.8 eV. However, it is possible to have a p-metal electrode with a higher work function about 5.0 eV. Another disadvantage of the MIPS with a metal electrode of Ta(CO)N is the relatively high resistivity of the Ta(CO)N layer.

Aspects of the invention are listed in claims 1, 9, 17 and 22.

Exemplary embodiments of the present invention are illustrated in the drawings and are explained in more detail in the description below.

In the figures:

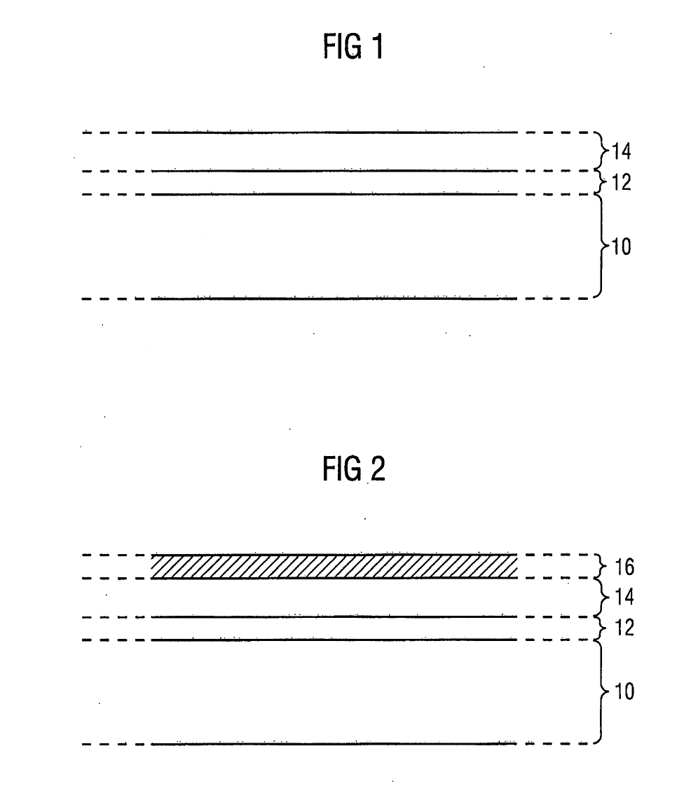

FIGS. 1-3 show various method steps for the fabrication of an integrated circuit device according to a first embodiment of the invention;

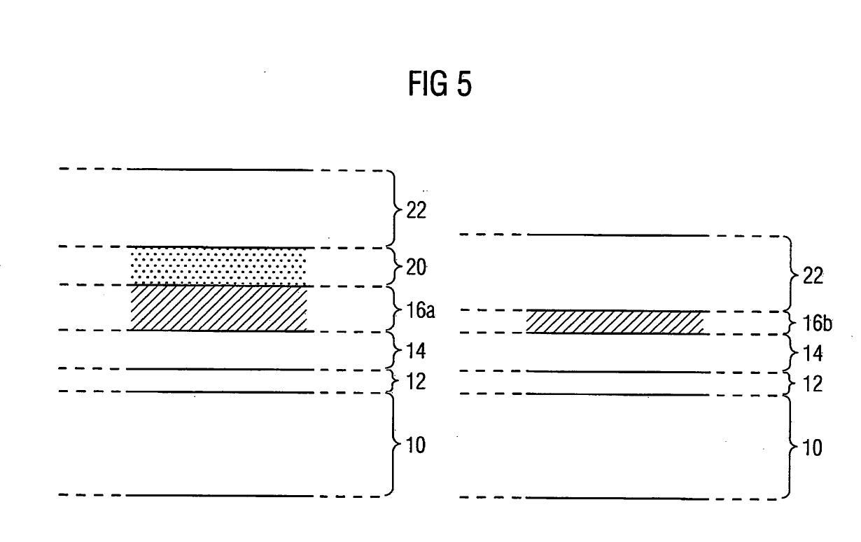

FIG. 4 shows an gate electrode structure with two different capping layers according to a second embodiment of the invention; and

FIG. 5 shows an integrated circuit device with a p-MOS structure and a n-MOS structure according to a third embodiment of the invention.

FIG. 1 to 3 show steps for fabricating the integrated circuit device with a gate electrode structure on a semiconductor substrate according to a first embodiment of the invention.

In FIG. 1 a semiconductor substrate 10 is provided. Said semiconductor substrate 10 consists of silicon. However, also other semiconductor materials such as germanium etc. are possible.

On the surface of the semiconductor substrate 10 a first insulating layer 12 of silicon dioxide is formed. If the semiconductor substrate 10 consists of silicon, the first insulating layer 12 can be formed by increasing the temperature of the semiconductor substrate 10 and exposing the semiconductor substrate 10 to an oxygen atmosphere simultaneously. Alternatively the first insulating layer 12 can be formed on the semiconductor substrate by a Physical Vapor Deposition (PVD) Process, by a Chemical Vapor Deposition (CVD) Process or by wet chemical oxidation.

In the next step of the fabrication method a second insulating layer of a high-K dielectric material is formed on the first insulating layer. Such a high-K dielectric material can be selected from the group of HfSiO, HfO, ZrSiO, ZrO, HfZrO, HfZrSiO, HfAlO, ZrAlO, HfREO or ZrREO, where RE is a rare earth element of the group Y, Sc, La, Nd, Pr, Dy, Er, Yb, Lu, Tb, Sm, Gd, Ho or Ce. The use of HfREO, ZrREO, HfAlO or ZrAlO can additionally modify the work function of the fabricated gate electrode structure. In an alternative implementation different dielectrics are used for N- and P-channel transistors on the same substrate.

In FIG. 2 a thin layer of niobium carbo oxynitride (Nb(CO)N) 16 is formed on the surface of the semiconductor substrate 10 with the two insulating layers 12 and 14 of FIG. 1. The Nb(CO)N layer 16 has a layer thickness of less than or equal to 10 nm and is formed by a CVD process, i.e. by an Atomic Layer Deposition (ALD) process. It is possible to deposit the Nb(CO)N layer 16 by a Metal Organic (MO) ALD/CVD/AVD process with a high residual carbon content to make sure that the Nb(CO)N layer 16 has a relatively high surface area and is amorphous. The oxidation can take place in an oxygen containing atmosphere or due to the use of the following reactants: O₂, O₃, H₂O, H₂O₂, NO and/or NH₃.

After the deposition of the Nb(CO)N layer 16 the percentage of carbon is between 0 to 20%, the percentage of oxygen is between 2 to 30%, and the percentage of nitrogen is between 5 to 60% within the Nb(CO)N layer 16. It is possible to increase the oxygen content within the Nb(CO)N layer 16, as compounds with oxygen have a higher electro-negativity than compounds with nitrogen or carbon. However, as pure oxides of niobium are dielectric, additional carbon and nitrogen atoms are required. For the deposition of the Nb(CO)N layer 16, similar precursors can be used as for the deposition of a tantalum containing layer.

Compared to a tantalum layer for a gate electrode structure, for the Nb(CO)N layer 16 a dielectric niobium phase corresponding to the Ta₃N₅ phase does not exist. Therefore, all compounds of niobium with sufficient N or C content are expected to be conductive. Also, the niobium compounds should have a slightly higher work function than tantalum compounds due to the higher electro-negativity of niobium compared to tantalum.

As an alternative to the Nb(CO)N layer 16, the integrated circuit device of FIG. 2 might also have a conductive layer of a composition of vanadium, chromium, tungsten and/or molybdenum with carbon, oxygen and nitrogen. The properties explained above are also realized by such a conductive layer.

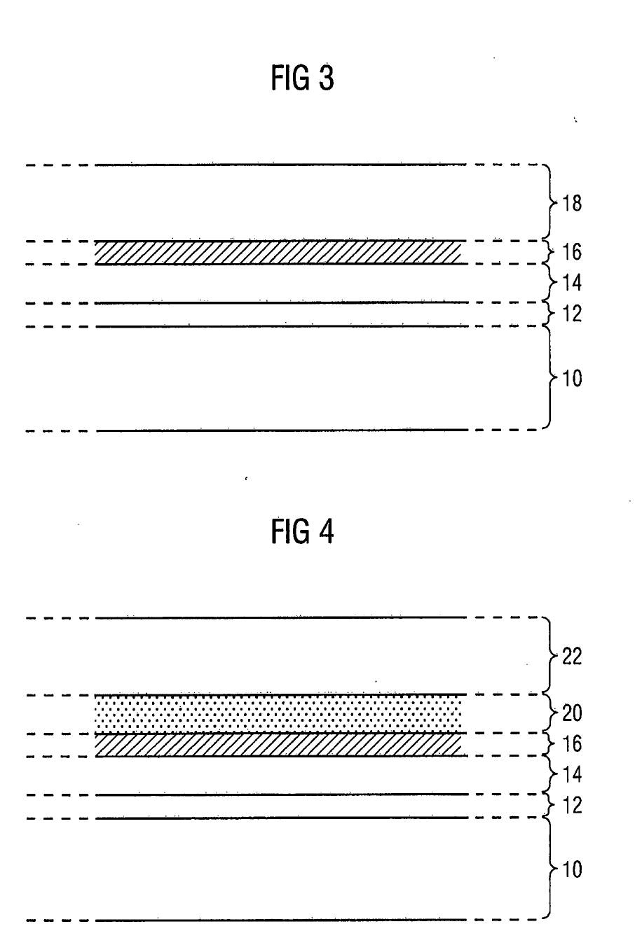

In FIG. 3 a capping layer 18 is added to the silicon substrate 10 with the two insulating layers 12 and 14 and the Nb(CO)N layer 16 of FIG. 2. Such a capping layer 18 can consist of polysilicone or a high density metal, for example TiN, TaN, Mo, MoN, WN, or W. A capping layer 18 of such a high density metal can be formed by a PVD or a CVD process. The fabrication process for a gate electrode is then continued as generally known.

FIG. 4 shows an example for a p-MOS structure according to a second embodiment of the invention. The gate electrode structure consists of a semiconductor substrate 10, i.e. of silicon. On the surface of the semiconductor substrate 10 a silicon dioxide layer 12 is formed. This silicon dioxide layer 12 serves as a first insulating layer 12 of the p-MOS structure. A second insulating layer 14 is formed on the first insulating layer 12. This second insulating layer 14 consists of a high-K dielectric material, for example HfSiO, HfO, ZrSiO, ZrO, HfAlO, ZrAlO, HfZrO, HfZrSiO, HfREO or ZrREO.

On the second insulating layer 14 a metal layer 16 has been formed of a combination of niobium, vanadium, chromium, tungsten and/or molybdenum together with carbon, oxygen and nitrogen. This metal layer 16 serves as a metal electrode for the p-MOS structure. In this metal layer 16 the percentage of carbon is between 0 to 20%, the percentage of oxygen is between 2 to 30% and the percentage of nitrogen is between 5 to 60%. This combination of the materials carbon, oxygen and nitrogen with at least one of the metals niobium, vanadium, chromium, tungsten and/or molybdenum can be achieved by the fabrication method explained in the FIG. 1 to 3.

On the surface of the metal layer 16 a first capping layer 20 is deposited. This first capping layer 20 contains at least one of the following materials: Mo, MoN, W, WN, TiN, or TaN. On the first capping layer 20 a second capping layer 22 of polysilicone is formed.

As the second capping layer consists of polysilicone, there is the risk that oxygen or nitrogen could diffuse from the metal layer 14 into the second capping layer 22. Therefore, the first capping layer 20 is inserted between the metal layer 16 and the second capping layer 22 of polysilicone to prevent the removal of oxygen or nitrogen from the metal layer 16 into the second capping layer 22.

In FIG. 5 the layer thicknesses of different layers of a p-MOS structure and a n-MOS structure are compared with each other. The p-MOS structure consists of a silicon dioxide layer 12, a high-K dielectric layer 14, a metal layer 16a containing niobium, vanadium, chromium, tungsten and/or molybdenum in a combination with carbon, oxygen and nitrogen, a first capping layer 20 of W and a second capping layer 22 of polysilicone. However, the first capping layer 20 could also comprise Mo, MoN, TiN, TaN and/or WN. The high-K dielectric layer 14 could be formed i.e. of HfSiO, HfO, ZrSiO, ZrO, HfAlO, ZrAlO, HfZrO, HfZrSiO, HfREO and/or ZrREO.

The n-MOS structure has the same two insulating layers 12 and 14 as the p-MOS structure. Also, on the surface of the second insulating layer 14 a metal layer 16b of the material niobium, vanadium, chromium, tungsten and/or molybdenum has been deposited. However, compared to the metal layer 16a of the p-MOS structure, the metal layer 16b has the same or a decreased layer thickness. Also, the polysilicone capping layer 22 has been formed in touch with the surface of the metal layer 16b of the n-MOS structure. Thus the n-MOS structure lacks the metallic capping layer 20 of W.

The capping layer on the metal layer 16a or 16b can increase the work function of a p-MOS. Also, a capping layer of TiN, TaN, Mo, MoN, WN and/or W can prevent the reduction of the metal by the polysilicone. Thus, in the example of FIG. 5 the p-MOS structure has two different capping layers while the n-MOS structure only has one capping layer of polysilicone.

What is claimed is:

1. Integrated circuit device comprising:
a semiconductor substrate, and
a gate electrode structure on the semiconductor substrate comprising:
at least one insulating layer of dielectric material on said semiconductor substrate and
a metal layer on said at least one insulating layer, said metal layer containing niobium (Nb), vanadium (V), chromium (Cr), tungsten (W) and/or molybdenum (Mo).

2. Integrated circuit device of claim 1, wherein said metal layer contains a composition of niobium, vanadium, chromium, tungsten and/or molybdenum with carbon (C), oxygen (O) and nitrogen (N).

3. Integrated circuit device of claim 2, wherein the percentage of carbon is between 0 to 20%, the percentage of oxygen is between 2 to 30%, and the percentage of nitrogen is between 5 to 60% in said metal layer.

4. Integrated circuit device of claim 1, wherein said at least one insulating layer comprises an insulating layer of a high-k dielectric material, preferable of at least one of the following materials: HfSiO, HfO, ZrSiO, ZrO, HfAlO, ZrAlO, HfZrO, HfZrSiO, HfREO or ZrREO.

5. Integrated circuit device of claim 4, wherein the gate electrode structure has a silicon dioxide (SiO₂) layer between the semiconductor substrate and the insulating layer of a high-k dielectric material.

6. Integrated circuit device of claim 1, wherein the gate electrode structure has at least one capping layer of conductive material on said metal layer, preferable of at least one of the following materials: polysilicone, TiN, TaN, Mo, MoN, WN and/or W.

7. Integrated circuit device of claim 6, wherein the gate electrode structure has a first capping layer on said metal layer, preferable of TiN, TaN, Mo, MoN, WN and/or W, and a second capping layer on said first capping layer, preferable of polysilicone.

8. Integrated circuit device of claim 1, wherein said metal layer has a layer thickness of less than or equal to 10 nm.

9. Integrated circuit device comprising:
a semiconductor substrate with a first p-doped region and a second p-doped region, and
a p-MOS structure on the semiconductor substrate, which extends between the first and the second p-doped region, said p-MOS structure comprising:
at least one insulating layer of dielectric material on said semiconductor substrate and
a metal layer on said at least one insulating layer, said metal layer containing niobium (Nb), vanadium (V), chromium (Cr), tungsten (W) and/or molybdenum (Mo).

10. Integrated circuit device of claim 9, wherein said metal layer contains a composition of niobium, vanadium, chromium, tungsten and/or molybdenum with carbon (C), oxygen (O) and nitrogen (N).

11. Integrated circuit device of claim 10, wherein the percentage of carbon is between 0 to 20%, and the percentage of oxygen is between 2 to 30%, and the percentage of nitrogen is between 5 to 60% in said metal layer.

12. Integrated circuit device of claim 9, wherein said at least one insulating layer comprises an insulating layer of a high-k dielectric material, preferable of at least one of the following materials: HfSiO, HfO, ZrSiO, ZrO, HfAlO, ZrAlO, HfZrO, HfZrSiO, HfREO or ZrREO.

13. Integrated circuit device of claim 12, wherein the p-MOS structure has a silicon dioxide (SiO₂) layer between the semiconductor substrate and the insulating layer of a high-k dielectric material.

14. Integrated circuit device of claim 9, wherein the p-MOS structure has at least one capping layer of conductive material on said metal layer, preferable of at least one of the following materials: polysilicone, TiN, TaN, Mo, MoN, WN and/or W.

15. Integrated circuit device of claim 14, wherein the p-MOS structure has first capping layer on said metal layer, preferable of TiN, TaN, Mo, MoN, WN and/or W, and a second capping layer on said first capping layer, preferable of polysilicone.

16. Integrated circuit device of claim 8, wherein the metal layer has a layer thickness equal to or less than 10 nm.

17. Integrated circuit device comprising:
a semiconductor substrate with a first p-doped region and a second p-doped region and a first n-doped region and a second n-doped region, and
a p-MOS structure on the semiconductor substrate, which extends between the first and the second p-doped region, said p-MOS structure comprising:
at least one first insulating layer of dielectric material on said semiconductor substrate, and
a first metal layer on said at least one first insulating layer, said metal layer containing niobium (Nb), vanadium (V), chromium (Cr), tungsten (W) and/or molybdenum (Mo) of a first layer thickness, and
a n-MOS structure on the semiconductor substrate, which extends between the first and the second n-doped region, said n-MOS structure comprising:
at least one second insulating layer of dielectric material on said semiconductor substrate, and
a second metal layer on said at least one first insulating layer, said metal layer containing niobium (Nb), vanadium (V), chromium (Cr), tungsten (W) and/or molybdenum (Mo) of a second layer thickness, which differs from the first layer thickness.

18. Integrated circuit device of claim 17, wherein the p-MOS structure has a first capping layer of polysilicone on the first metal layer and the n-MOS structure has a second capping layer of polysilicone on the second metal layer.

19. Integrated circuit device of claim 18, wherein the p-MOS structure has a metallic capping layer inserted between the first metal layer and the first capping layer, while within the n-MOS structure said second capping layer is in touch with the second metal layer.

20. Integrated circuit device of claim 19, wherein said metallic capping layer of the p-MOS structure comprises at least one of the following materials: TiN, TaN, Mo, MoN, WN and/or W.

21. Integrated circuit device of claim 17, wherein said first insulating layer and said second insulating layer consist of different high-k dielectric materials, preferable two of the following materials: HfSiO, HfO, ZrSiO, ZrO, HfAlO, ZrAlO, HfZrO, HfZrSiO, HfREO or ZrREO.

22. Method of forming an integrated circuit device comprising the steps:
providing a semiconductor substrate,
forming at least one insulating layer of dielectric material on said semiconductor substrate and
forming a metal layer comprising niobium (Nb), vanadium (V), chromium (Cr), tungsten (W) and/or molybdenum (Mo) on the at least one insulating layer of dielectric material.

23. The method of claim 22, wherein said metal layer is formed of a composition of niobium, vanadium, chromium, tungsten and/or molybdenum with carbon, oxygen and nitrogen.

24. The method of claim 22, wherein at least one of said at least one insulating layer of dielectric material is formed of a high-k dielectric material, preferable of at least one of the following materials: HfSiO, HfO, ZrSiO, ZrO, HfAlO, ZrAlO, HfZrO, HfZrSiO, HfREO or ZrREO.

25. The method of claim 24, wherein a silicon dioxide (SiO₂) layer is formed between the semiconductor substrate and the insulating layer of a high-k dielectric material.

26. The method of claim 22, wherein at least one capping layer of conductive material is formed on the metal layer, preferable of at least one of the following materials: polysilicone, TiN, TaN, Mo, MoN, WN and/or W.

27. The method of claim 22, wherein said metal layer is formed with a layer thickness equal to or less than 10 nm.

28. The method of claim 22, wherein said metal layer is formed by a Chemical Vapor Deposition (CVD) process, preferable by an Atomic Layer Deposition (ALD) process.

29. The method of claim 28, wherein an oxidation is carried out during the CVD process, preferable with O₂, O₃, H₂O, H₂O₂, NO and/or NH₃ as reactant.

30. The method of claim 29, wherein after the CVD process, the percentage of carbon is between 0 to 20%, the percentage of oxygen is between 2 to 30%, and the percentage of nitrogen is between 5 to 60% in said metal layer.
